(19) United States
(12) Patent Application Publication
(10) Pub. No.: US 2006/0179849 A1
(43) Pub. Date: Aug. 17, 2006

(54) Peltier based heat transfer systems

(76) Inventors: Vladimir Semenovich Abramov, Moscow (RU); Valeriy Petrovich Sushkov, Moscow (RU); Yuriy Grigirievich Polistanskiy, Moscow (RU); Alexander Valerievich Shishov, Bykovo (RU); Nikolay Valentinovich Scherbakov, Moscow (RU)

Correspondence Address: Joseph Page, P.O. Box 757, La Jolla, CA, 92038, US

(21) Appl. No.: 11/057,926

(22) Filed: Feb. 14, 2005

(51) Int. Cl. F25B 21/02; H01L 35/28

(52) U.S. Cl. 62/3.3; 62/3.7; 136/204

(57) ABSTRACT

Heat transfer systems are presented with improved heat dissipation schemes based upon an asymmetric arrangement of Peltier elements to form a hot side of greater area than the cold side. This permits greater heat dissipation at the hot side of the heat transfer device into a suitable heat sink. A substantially planar system of radial symmetry is the basis of a highly efficient heat spreading scheme. The ‘spokes’ of the system are pie-wedge shaped Peltier semiconductor elements having a small heat transfer junction at one end and large heat transfer junction at the other. In best versions, a concentric ring scheme has a cooled area at the center and a heat dump at the periphery. Semiconductor Peltier elements connect the two and provide a vehicle to carry heat radially away from a heat point source thermally coupled to the heat transfer system at an active area. These special arrangements are provided while still maintaining the necessary serial electronic circuit and parallel thermal circuit.

### BACKGROUND OF THE INVENTIONS

1. Field

The following invention disclosure is generally concerned with: solid state heat transfer systems and specifically concerned with highly efficient Peltier effect semiconductor cooling systems.

2. Prior Art

Peltier effect heat transfer systems have enjoyed considerable success in various applications. They are clean, simple with no moving parts, long lasting, easy to use, reliable, among other things. In brief alternating ‘P’ type and ‘N’ type doped semiconductor elements are connected together to form a serial electronic circuit and a parallel thermal circuit. At each PN junction, electrons are driven from the conduction band of the ‘N’ material, into lower energy levels of the conduction band in the ‘P’ materials. This is necessarily accompanied by localized heating in the junctions and/or connector as the energy difference becomes converted to heat. Conversely, when electrons pass from a ‘P’ type material into a ‘N’ type material, the electrons are promoted to higher energy levels and absorb energy; i.e. cooling occurs in these types of junctions. When these devices are arranged such that heating occurs in one location and cooling in another, the result is a heat transfer system having wonderful characteristics.

In some high performance systems known in the art, a first stage Peltier cooler is coupled to a second stage cooler. The first stage may have a small surface area ‘cold side’ and a ‘hot side’ (of similar size) coupled to a large ‘cold side’ of the second stage. The thermal load of the second stage is higher than the first and it is advantageous to deploy that second stage in a configuration of increased surface area, that is increased surface area in comparison to the first stage. This can be seen in many versions of systems presented by experts in the literature. In particular, FIG. 1 of U.S. Pat. No. 5,515,683 shows such arrangement. Various alternative versions will also be found in other places.

While Peltier type, all-electronic, heat transfer systems are quite well known, these are generally deployed with geometries necessary to support the primary characteristics associated with a large plurality of semiconductor elements simultaneously arranged in a serial electronic circuit and a parallel thermal circuit. Most typically, a plurality of roughly cubic, alternately doped semiconductor elements is distributed over a planar region to yield an opposing ‘cold side’ and ‘hot side’; i.e. the parallel thermal circuit. This is a well known standard arrangement.

It is notable that the terms ‘hot side’ and ‘cold side’ are quite standard in the industry. These terms come from the fact that physical construction constraints tend to demand that many thin semiconductor elements are laid about in a planar region and are typically sandwiched between buffer substrates on either side to form a thin planer device in which one side cools while the other heats. Although alternative arrangements are possible, it is nearly invariable that Peltier cooling systems are configured this way.

In Fritz et al, U.S. Pat. No. 5,515,238 a system is presented with reduced spacing between semiconductor elements thereby improving its performance. However, these systems adopt similar architecture as their predecessors and have area ratios, hot side/cold side which are quite close or equal to one.

One notable exception is taught by Douglas Hoffman in a vapor compression cycle refrigeration system of U.S. Pat. No. 5,361,587. Because Hoffman deploys his thermoelectric cooler as a gas condenser, it is quite inconvenient to bring gas into contact with a planar surface. So, Hoffman arranges his doped semiconductor elements about the outside surface of a cylinder in which gas can be made to flow. He improves the surface area of the heated portion by adding cooling fins to increase the heat transfer to passing air.

Another important new development in related arts includes the disclosure of US Patent Application Publication numbered: 2004/0120156 A1 of Jun. 24, 2004. These inventions relate to combinations of Peltier cooling systems with LED devices to effect a high performance/high power light source. The suggested devices are brilliant systems having great potential to provide exceptional lighting performance features. However, they are constructed upon “out-of-the-plane” technologies well know in Peltier system arrangements. Further, they do not provide asymmetrical cool/hot areas which yield advantage to point type heat sources such as the LEDs being cooled with the device.

While systems and inventions of the art are designed to achieve particular goals and objectives, some of those being no less than remarkable, these inventions have limitations which prevent their use in new ways now possible. Inventions of the art are not used and cannot be used to realize the advantages and objectives of the inventions taught herefollowing.

### SUMMARY OF THE INVENTIONS

Comes now, Abramov, V. S.; Sushkov, V. P.; Polistanskiy, Y. G.; Shishov, A. V.; and Scherbakov, N. V., with inventions of heat transfer systems including semiconductor devices for highly localized cooling. It is a primary function of these systems to provide efficient heat management to improve the performance and lifetime of a device otherwise susceptible to damage from heat energy.

Point Source

A first distinguishing factor can be found in the fact that these systems are designed for point heat sources. Cold portions of these systems are arranged as a small circular ‘point’. As such, they are particularly suitable for small single element semiconductor heat sources such as lasers and light emitting diodes. Thermal electric coolers of the art are almost exclusively designed to couple with large area planar heat sources. As such systems of the art typically have a large area cold plane.

Another primary distinguishing feature of inventions presented herein relates to asymmetric hot and cold areas. Systems first taught here include a cold area having a size much smaller than the size of the hot area. As such, a greater capacity to dissipate heat is realized. In these systems, ‘cold sides’ of the art are translated to a small circular area in these systems. A cold area is made far smaller than the warm area to which it is connected. As such, the heat transfer power, is ‘focused’ to a small point and concentrated. This supports cooling of devices which are heat point sources. These arrangements provide a leveraged advantage; as heat dissipation depends upon the area over which heat may be transferred.

When the hot area is large in comparison to the cold area, an advantage is realized whereby the cold area is far more effectively cooled than when the areas are similar as commonly found with systems known in the art. Typically, the cold side and hot side of a Peltier cooler are each separated from ambient temperature by approximately the same temperature difference. When the cold area is much smaller than the hot area, an asymmetric temperature difference is realized. The cold area is considerably colder than ambient temperature when compared to the amount by which the hot area is hotter than ambient temperature. Such asymmetric temperature difference favors heat transfer system objectives in preferred versions as will be more clear in view of the full disclosure herefollowing.

These systems are further distinct from those in the art as they are build into a single plane architecture. In best versions, a cold area, a hot area, and Peltier heat transfer elements all lie in the same plane. By comparison, the art only contains those having parallel planes separated and space from one-another in an orthogonal direction. Here, a circular cold area lies concentric with a annular hot area of far greater size. These are coupled together via Peltier element arranged in a radial fashion. Accordingly, present inventions include radically different thermal circuits of rather distinct geometry. While still maintaining a serial electric circuit, a radial distribution of semiconductor components forms concentric areas in a single plane which correspond to a ‘hot side’ and a ‘cold side’ known in common Peltier devices. In best versions, a ‘cold area’ lies concentric with and interior to a ‘hot area’; both lying substantially in the same plane. A flat planar arrangement is advantageous as it cooperates well with the two dimensional architecture of electronic circuit boards. Peltier heat transfer systems of these inventions can be considered two dimensional devices in striking comparison to the more typically three dimensional systems having significant extent along a normal axis with respect to the planes in which they are built.

In most general terms, heat transfer systems of these inventions are defined as being comprised of: one or more semiconductor pair of at least one ‘P’ type and one ‘N’ type element, each element having a cold end and a hot end, further having an active area thermally coupled to the cold ends and a heat dump thermally coupled to the hot ends, whereby the heat dump is appreciably larger in area than the active area. Thus, these systems benefit from an efficient heat spreading scheme where heat from a very small area (source) is distributed to comparatively very large areas via Peltier effect semiconductor elements.

### OBJECTIVES OF THESE INVENTIONS

It is a primary object of these inventions to provide electronic heat transfer systems.

It is an object of these inventions to provide heat transfer systems having an improved area ratio with respect to hot and colds ‘sides’.

It is a further object to provide systems compatible and cooperative with the planar nature of circuit board topology.

It is an object of these inventions to provide heat transfer systems most suitable for point source heat generating elements.

A better understanding can be had with reference to detailed description of preferred embodiments and with reference to appended drawings. Embodiments presented are particular ways to realize these inventions and are not inclusive of all ways possible. Therefore, there may exist embodiments that do not deviate from the spirit and scope of this disclosure as set forth by appended claims, but do not appear here as specific examples. It will be appreciated that a great plurality of alternative versions are possible.

### BRIEF DESCRIPTION OF THE DRAWING FIGURES

These and other features, aspects, and advantages of the present invention will become better understood with regard to the following description, appended claims and drawings where:

FIG. 1 is basic illustration in perspective which shows a minimal system of most simple arrangement;

FIG. 2 illustrates a more sophisticated and detailed version of heat transfer systems having similar radial character;

FIG. 3 is a cross section diagram to further illustrate major components and their relationships with one another in an alternative version;

FIG. 4 is similarly a cross section diagram which includes ancillary elements in working positions;

FIG. 5 is a current path diagram to illustrate the series electrical circuit;

FIG. 6 shows the heat circuit which is “parallel”; yet more importantly radial in nature;

FIG. 7 is a diagram showing a repeat element in isolation from an entire device;

FIG. 8 shows a device having a quarter section cut away so reference numerals can be placed to address in detail important regions at the center;

FIG. 9 shows an alternative version with similar performance but simplified construction;

FIG. 10 is a diagram of the prior art and the traditional and more obvious way of realizing benefit from a high cold side/hot side area ratio for comparison;

FIG. 11 is an exploded view to illustrate ancillary systems which may be combined with the basis presented here.

### GLOSSARY OF SPECIAL TERMS

Throughout this disclosure, reference is made to some terms which may or may not be exactly defined in popular dictionaries as they are defined here. To provide a more precise disclosure, the following terms are presented with a view to clarity so that the true breadth and scope may be more readily appreciated. Although every attempt is made to be precise and thorough, it is a necessary condition that not all meanings associated with each term can be completely set forth. Accordingly, each term is intended to also include its common meaning which may be derived from general usage within the pertinent arts or by dictionary meaning. Where the presented definition is in conflict with a dictionary or arts definition, one must use the context of use and liberal discretion to arrive at an intended meaning. One will be well advised to error on the side of attaching broader meanings to terms used in order to fully appreciate the depth of the teaching and to understand all the intended variations.

Semiconductor element—a semiconductor element is a bulk material typically formed as a crystal which may be doped with an impurity (or impurities) to form a lattice which supports transmission of electrical currents.

Semiconductor element pair—a semiconductor element pair includes one ‘P’ type doped semiconductor element and one ‘N’ type doped semiconductor element in a similar crystal both in composition and geometry.

Heat source—is a device which generates heat and enjoys improved performance when cooled by a heat transfer system.

Heat dump—a heat dump is a thermal body into which heat may be transmitted and passed from a heat transfer system.

‘Hot area’—a hot area of these heat transfer systems roughly corresponds to the ‘hot side’ of a common Peltier cooler except that its geometry is not a ‘side’ but rather an area of typically circular section.

‘Cold area’—a cold area of these heat transfer systems roughly corresponds to the ‘cold side’ of a common Peltier cooler except that its geometry is not a ‘side’ but rather an area of typically circular section.

Active area—an active area includes the junction between a heat source and a cold area of a heat transfer system.

While ‘hot area’ and ‘cold area’ are used extensively throughout this disclosure, it will be understood by experts that reversal of the current will reverse the heating/cooling action at each, thus hot areas become cold areas and visa-versa. Cooling at the center is suggested throughout for consistency but lost of generalization is not intended by this nomenclature and reversal is fully anticipated for point source heating or temperature stabilization applications.

### PREFERRED EMBODIMENTS OF THESE INVENTIONS

In accordance with each of preferred embodiments of these inventions, there is provided apparatus for heat transfer. It will be appreciated that each of the embodiments described include an apparatus and the apparatus of one preferred embodiment may be different than the apparatus of another embodiment.

Systems described herefollowing are primarily distinctive and characterized by the following features: 1) the ‘cold side’ is fashioned as a point or very small circular area; 2) the system is embodied in a substantially planar scheme having a radial pattern; and 3) the hot/cold area ratio is high or greater that about 1.2. These features can only be realized via the very unique and new geometries which will become apparent in the following presentation.

The cooled portion of these special heat transfer devices can be very small indeed. The geometric nature of the devices permits a ‘cold area’ which approximates a point. All the cooling action is focused into a very small portion at the center of a radially symmetric configuration. As such, these systems are most appropriate for use in conjunction with systems which demand heat control at a point as opposed to the cooling in a planar section commonly found in art.

The geometric nature of these systems are further distinct in that their components are built in a common plane quite unlike their better known cousins. That is, the cold area, the hot area, and the transfer elements (Peltier elements) are all in approximately the same plane; by ‘approximately in the same plane’ it is meant that the aspect ratio of these devices may be about 5 or greater. The hot and cold areas may be coplanar and are generally concentric. In the art, systems are built in the orthogonal direction with respect to a first cooling plane, a second heating plane and the space therebeween which is necessarily not zero or thin. Because of this new arrangement, these systems can be supported in normal circuit board construction and deployment. These systems can be built integrally therewith other electronics on a single circuit board; the Peltier elements being inserted or soldered alongside resistors, capacitors, ICs, et cetera. Peltier coolers of the arts are added to circuit boards into space reserved for them and their hosted device is added to a coupling at the cooling plane. They are not formed integrally with the common circuit board components. A major distinction of these systems is immediately obvious in consideration of the fact that the hot and cold areas (along with circuit traces, active area, et cetera) are coplanar.

Finally, one may consider the ratio of area sizes—the cold area with respect to the warm area. A most effective heat transfer system distributes or dissipates heat into a heat dump. The larger the heat dump, the more effective it may sink heat. The geometric nature of these systems and their unusual configurations permit very high ratio of hot area to cold area which improves the effectiveness of the system task at hand: heat transfer. These systems couple to a virtual point; while common Peltier systems couple to a large 2 dimensional flat area.

In addition to the core heat transfer systems, these inventions also include heat transfer systems in combination with special high performance electronic devices and specially configured heat sinks. These systems interface with special heat generation devices such as a high performance semiconductor lasers or light emitting diodes for example; heat point sources. That is, these sources are considerably small and may highly localized heat generation mechanisms. In this regard, they cooperate very well with the radial geometry suggested throughout this presentation. One might consider the heat transfer systems presented here an efficient bridge between a high performance heat point source and a spatially distributed heat dump. Further, these systems are primarily built in a single plane raising their compatibility with circuit board technologies. They may be fabricated in automated systems supporting common circuit board manufacture; a considerable advantage.

The cold area configured as a small circular area is ideally suited to accommodate therein a single element high performance electronic device, for example a Quantum Cascade Laser, which benefits greatly from operation at reduced temperatures. Similarly, high output light emitting diodes, LEDs, can have higher light output when they are aggressively cooled by active devices such as the heat transfer systems taught here. As the LED is virtually a point source, its geometry cooperates with the cold area of these heat transfer systems. Other devices which will enjoy benefits particular to these systems also include detector systems—in particular infrared detectors which have greatly reduced noise when operated in a cooled state. Thus, these inventions include radially configured Peltier cooling systems in conjunction with a point, single element electronic heat source; either semiconductor lasers, light emitting diodes, and photodetectors by way of example.

In addition, it is not merely a cooling function in which these devices are well suited, but rather temperature stabilization at a point. Since these heat transfer systems are particularly powerful at finite and small areas, electronic devices having that property and which benefit from temperature stabilization, will find greatly improved performance when used together. The high area ratio further magnifies the ability of these systems to quickly respond to temperature changes and correct them in stabilization schemes. In contrast, a planar Peltier system has a far higher thermal momentum at the cold side and cannot quickly respond to need for a temperature adjustment.

Systems of these inventions also include the combination of heat transfer systems with heat sinks particularly configured for proper interface with such heat transfer systems having a particular geometric characteristic. That is, heat sink systems arranged with an annular interface which may be thermally coupled to the hot area of the heat transfer system. The hot area is the structure which permits output (heat) from the heat transfer system and thus, heat sinks which effective cooperate with these heat transfer systems are particular in their geometric construction as they will permit such interface. Examples are presented herefollowing of a cooling fin arrangement. One will also appreciate that other heat sinks having an annular receiving interface provide particular advantage to these heat transfer systems and are accordingly part of the combinations claimed here.

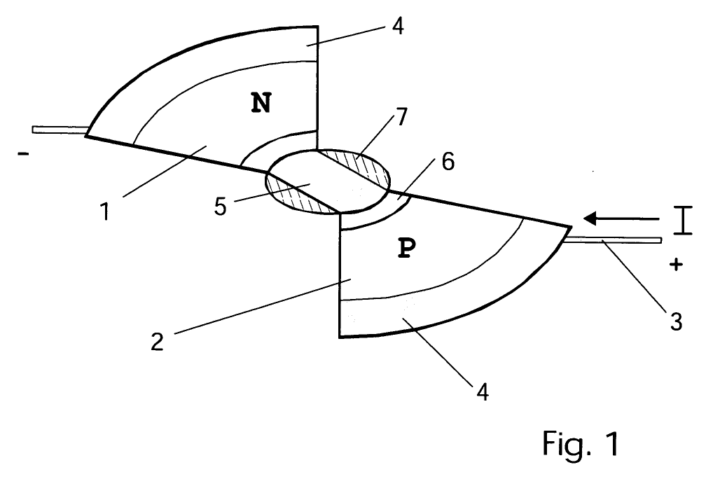

These inventions will be most clearly understood in view of examples including those which have reference to drawings appended hereto. In a most basic first illustrative example a heat transfer system with asymmetric heating/cooling areas is presented in FIG. 1. A Peltier semiconductor element pair is formed of: a first element 1, an ‘N’ type doped semiconductor material; and a second element 2, a ‘P’ type doped semiconductor material. In the present case, these semiconductor elements take a very special ‘pie-wedge’ shape with a truncated apex. An electrical circuit provides a current path 3 which enters the ‘P’ doped semiconductor via metallic connector 4. As the connector is metallic, i.e. a pure conductor, and the Peltier element is a semiconductor, energy will be gained or lost when electrons make the transition from one to the other. A connector preferably has a high thermal conductivity. The conductor provides an electrical path for electron current flowing in the thermocouples; i.e. from the ‘P’ device to the ‘N’ device and visa versa. Additionally, the connector provides a thermal path for heat which exits the thermocouples and gets transmitted via the connector into the heat dump which lies at the periphery of the device. Another metallic connector 5 joins the apex portions of the semiconductor elements with each other at junction region 6. In this way, the center region 7 is thermally coupled to both cold areas of the semiconductor elements. A heat source placed in the cooled area 7 will be reduced in temperature while the large areas at the system periphery will be heated. Heat will be transferred from the central portion of the device radially toward the larger area at the periphery where a suitable heat dump or heat sink may be appropriately coupled. While FIG. 1 is nicely useful for illustration purposes, it has limitations in a practical sense because it is comprised of but one Peltier semiconductor pair or ‘couple’. In preferred versions, there are a plurality of couples. But, this does not mean the geometries first suggested in FIG. 1 are not useful; quite contrarily, the geometry has excellent properties which aid the heat transfer objectives. It is these radial geometries which permit the asymmetric area sizes at the thermally opposing ‘sides’. In review, the geometry suggested in FIG. 1 converts the required parallel thermal circuit from a more traditional cylindrical sense to a radial planar arrangement.

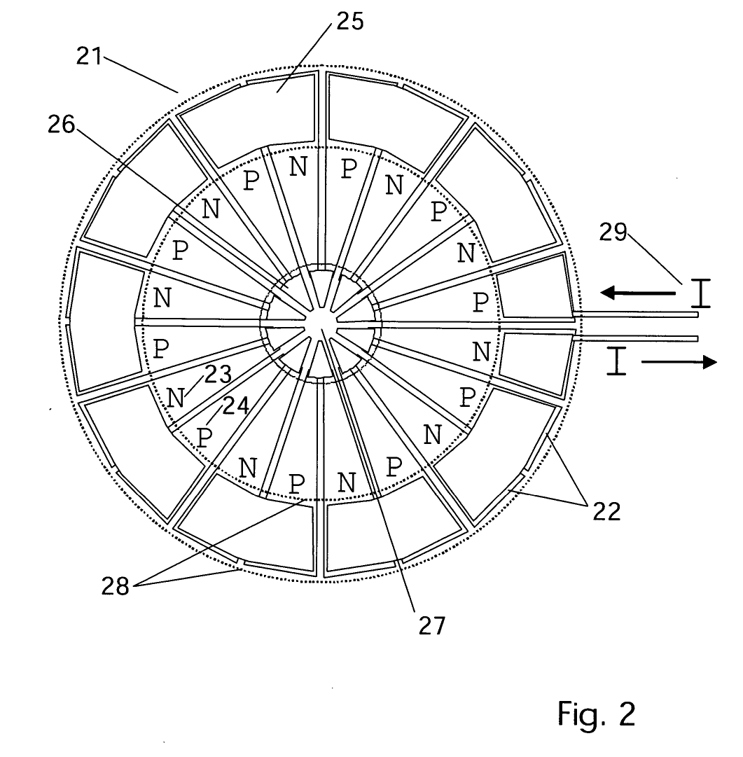

FIG. 2 more clearly shows a practical device in considerable detail. A heat transfer system 21 is comprised of a ‘wheel’ style configuration having therein a plurality of Peltier element heat transfer pairs. Specifically, ten semiconductor element pairs, each pair comprising one ‘P’-type doped semiconductor and one ‘N’-type doped semiconductor material, are arranged in a planar region of circular section and axial symmetry. The semiconductor elements may be shaped as ‘pie-wedges’ with an apex (sometimes truncated) coupled to an electrical connector arranged within a cold area, and peripheral ends 22 coupled to an electrical connector in a hot area to form a serial electronic circuit. As the Peltier effect demands, a semiconductor pair includes one ‘N’ type 23 and one ‘P’ type 24 element. Hot area connectors 25 and cold area connectors 26 electrically join the semiconductor elements to each other so that current may pass therethrough. The connectors also promote heat transfer from the semiconductor elements to the hot area and cold area. The connectors are not only good electrical conductors, but also good thermal conductors. This is in contrast to the semiconductor elements which are preferably good electrical conductors, but thermal insulators. When current passes from an ‘N’ type, through a connector, and to a ‘P’ type, heating occurs. When current passes from a ‘P’ type, through a connector, and to an ‘N’ type cooling occurs. Careful inspection of the systems represented in the drawing figures shows that heating occurs at the device periphery while cooling occurs at its center. Thus, we call the region 27 at the center, demarked by the circular dotted line, the ‘cold area’. A void at the centermost region is sometimes left to support placement therein of a heat load; i.e. an element in need of temperature control. Sometimes a disk of high thermal conductivity provides coupling between the heat load and the plurality of metal connectors. The area between dotted lines 28 is herein called the ‘hot area’. To be complete, the current direction 29 is specified. It is easy to appreciate that the size of the cold area is many times smaller than the size of the hot area. In preferred versions, the area ratio, hot/cold/ is at least or greater than about 1.2. This yields a temperature advantage which makes the temperature difference between the cold area and the ambient temperature greater than the temperature difference between the hot area and the ambient temperature. This asymmetric temperature difference is very useful. One might consider the system one which concentrates or focuses the cooling power of the devices into a small region. In effect a heat transfer ‘lens’.

In preferred versions, each element of the thermocouple is arranged in the shape of a pie-wedge portion. That is, a pseudo-triangular shape with its apex missing (see diagram). The tip of the apex is omitted in order that the centermost area is left empty. In some arrangements, this is required as this is the location into which the heat load is placed and connectors and Peltier elements might otherwise interfere with normal operation of this device.

The semiconductor elements may be semiconductor crystals formed in accordance with common semiconductor growing schemes. They are doped in accordance with designs whereby alternating elements are comprised of ‘N’ and ‘P’ type semiconductor material. In some versions, crystals may be first grown, then cut to preferred shapes, and cut with preferred crystalline orientation, then assembled into the designs taught here. This is particularly the case when it becomes desirable to manipulate the crystalline axis direction with respect to the device geometries. Thus these thermocouple elements may be formed separately and later soldered into place in the wheel framework device. Alternatively, the Peltier elements may be grown directly on a substrate. A two step process would permit all of the ‘P’ type elements to be grown at once. In a separate step, all of the ‘N’-type elements could be grown together.

Sometimes herein, we refer to the centermost region of a disk shaped device as the ‘active area’. Into the center we typically place a heat source and more specifically, a heat source having a geometric approximation of a point source. A laser for example, or other high power electronic device which produces significant heat but benefits from being cooled, is thermally coupled to the active area whereby the cooling effect brought by the heat transfer system is enjoyed by the high performance device.

Similarly, the ‘hot area’ at the system periphery is preferably coupled to a heat sink sometimes herein called a “heat dump”. In simple versions, the surrounding air is sufficient to carry away heat from the hot area and the hot area operates as a radiator. In some versions having high thermal loads, a cooling fin arrangement can aid in increasing further the area from which heat is spread. A cooling fin heat sink can be prepared for effective thermal coupling to the specially shaped annular hot area.

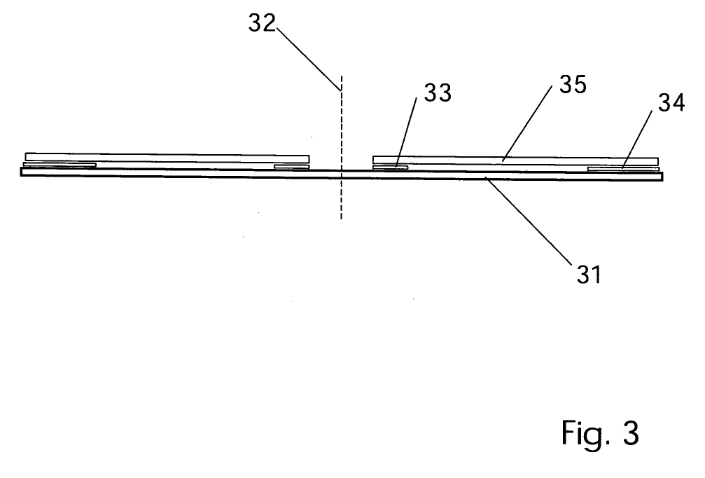

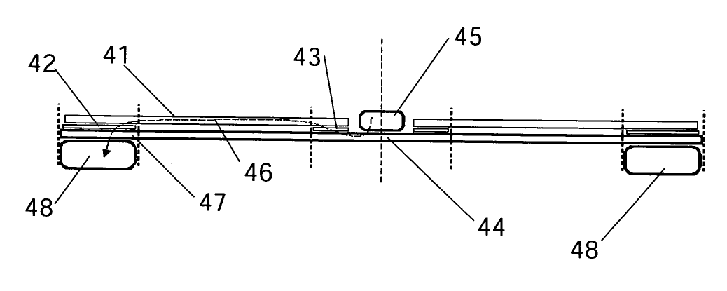

One can appreciate more fully the details of some preferred arrangements of these systems in view of a cross section diagram. While FIGS. 1 and 2 have presented systems with connectors applied at the tops of Peltier elements, this configuration was chosen mainly for clarity in the diagrams. It is not necessary that connectors be applied in the fashion shown but rather those connectors are sometimes better when they are positioned between the Peltier elements and the circuit board. They may maintain the same shape as those connectors of FIGS. 1 and 2; just their position with respect to the other elements is changed for illustration in FIGS. 3 and 4. The arrangements of FIGS. 3 and 4 are preferred and the connectors may be built as ‘circuit traces’ in standard circuit board and accompanying metal deposition technologies. The Peltier elements can thereafter be soldiered to the connectors on the circuit board.

Accordingly, FIG. 3 presents a substrate 31 which might be fashioned as a circuit board. An axis 32 defined a system symmetry. In a radially symmetric pattern, a plurality of cold area connectors 33 may be affixed or applied to the top surface of the circuit board near the central region of the device. Further, in a similarly radial pattern, hot area connectors 34 may be distributed in the circumferential region of the device. To the top surface of these connectors, a plurality of alternating “P” type and “N” type semiconductor elements 35 may be soldered or otherwise connected and affixed. The final structure would be similar to that shown as FIG. 2 with the exception that the connectors lie between the Peltier elements and the substrate.

One will more fully appreciate the advantages of such arrangements in view of the diagram presented as FIG. 4. Further, the heat path can be more readily appreciated in that diagram as another dimension is well represented. The main heat carrying body, Peltier element 41, forms a heat path which terminates at hot connector 42 and originates at cold connector 43. Cold area 44 may have thermally coupled therein a heat producing (or active) device 45 such as a high performance laser or LED. Dotted line 46 shows the path in which the heat from the active device is transmitted. Hot area 47 of the substrate couples heat from the hot connector 42 to a heat sink 48 where it may be further dissipated.

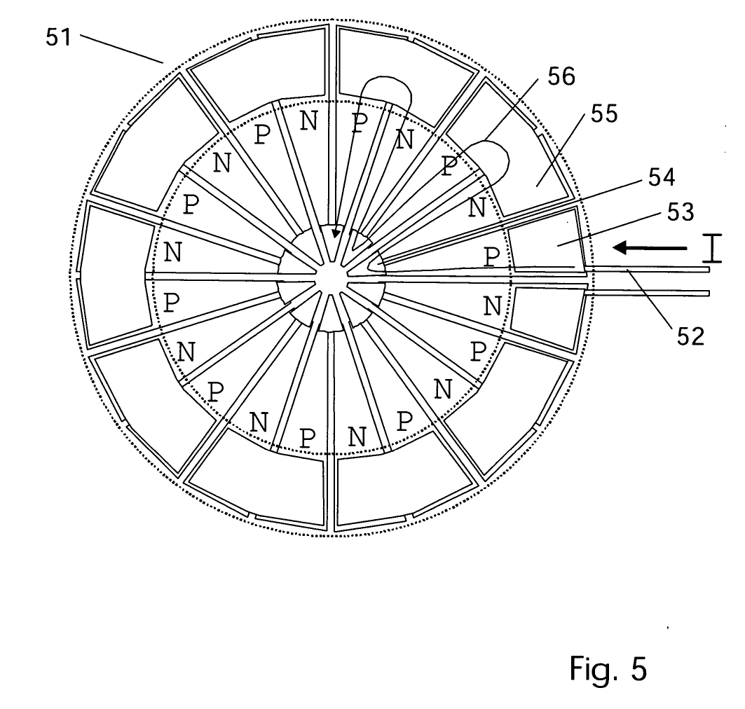

The electronic relationships between elements of these systems is better understood with reference to FIG. 5. As mentioned, preferred versions may include a single serial electronic circuit and this may be realized in the manner suggested in the drawing. A system 51 comprises ten Peltier semiconductor pairs of one ‘P’ type and one ‘N’ type element. An electrical lead 52 injects current into hot connector 53 at the periphery of a first ‘P’ element. The current is transmitted radially inward towards the center of the device where it enters, via a metallic cold connector 54, an ‘N’ type element. The current then continues radially outward to arrive at the disk periphery, or circumferential region, and another junction of ‘N’ and ‘P’ type materials 55 via a second hot connector. This time heating occurs and the current transfers heat energy collected at the center to the circle's exterior. The current then turns for another pass radially inward. It will be appreciated that by the time the current has left the device, it has participated in ten heating event and ten cooling events; all cooling taking place at the center and all heating taking place at or near the periphery. It will be further appreciated that the hot area is far larger than the cool area. Further, that the hot area is substantially in the same plane as the cold area. These are very important unique concepts associated with these devices.

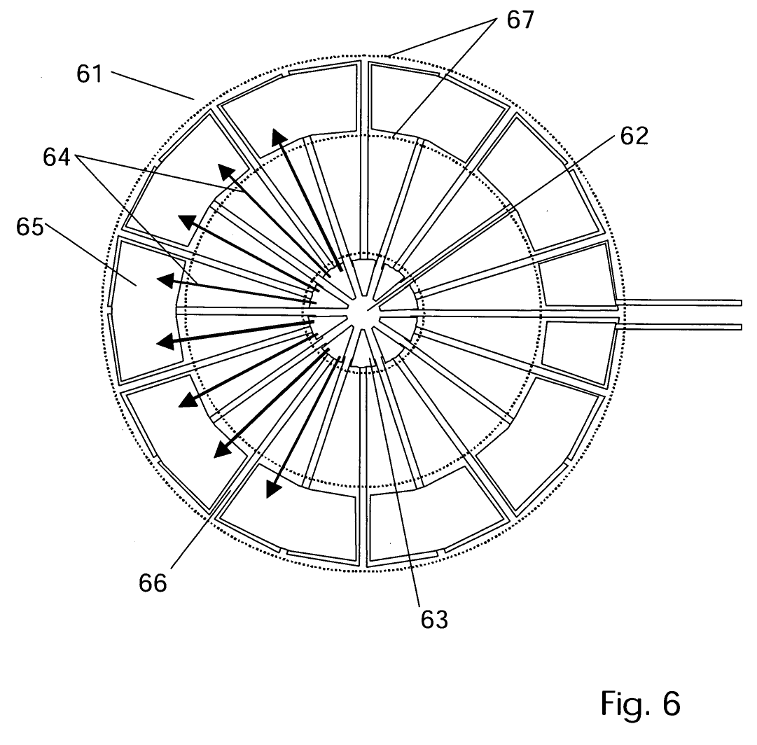

FIG. 6 is provided to illustrate the unique thermal circuit formed as part of these heat transfer systems. The arrangement, same as that of FIG. 5, provides a parallel thermal circuit. While experts in the art will be far more familiar with the term ‘parallel’ as it applies to the heat moving through all semiconductor elements in the same direction, i.e. from cold side to hot side, here the heat moves radially outward. As the heat is simultaneously moving in all elements in a similar fashion, the heat transfer is said to be ‘parallel’ despite an apparent conflict with a purely geometric meaning of ‘parallel’. The system 61 may be primarily characterized as a radial arrangement of pie-wedge shaped Peltier elements forming a cold area in the central portion of the device 62. Heat is taken up at the metallic connectors 63 and carried radially outward along ‘parallel’ heat paths 64. Heat is then deposited into connectors 65 which lie about the device periphery to form a hot area 66 which is demarked by concentric dotted lines 67.

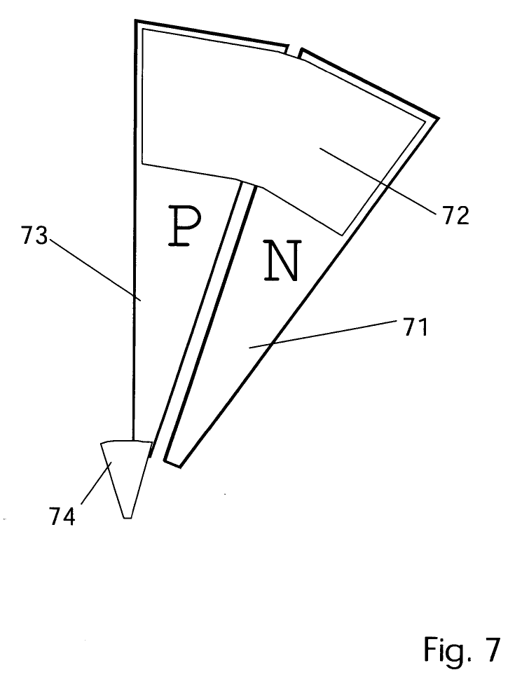

It is instructive to consider the repeat element of the systems described in the previous figures. FIG. 7 illustrates such construction. In a planar region, on approximately a 36 degree pie-wedge space the repeat element is formed of two semiconductor elements and two connectors as shown. A first semiconductor element 71 is ‘N’ type and connected via a metal conductor 72, a hot connector, to semiconductor element 73 of ‘P’ type doping. Finally, the repeat element includes cold conductor 74. This structure, repeated ten times, and rotated appropriately, can be used to realize the more complex arrangements depicted in prior drawing figures. This is shown here to suggest the simplicity of the devices. In addition, one can more readily appreciate the difference in size of the ‘cold area’ and the ‘hot area’ which can be approximated by the associated connector size. The difference in size works out to a favorable advantage as more heat can be displaced when the area into which it goes is large. To properly gain advantage from this effect, it is best if the hot area is significantly larger than the cold area. For this reason, these systems have a size ratio, hot area/cold area which is greater than 1.2. In preferred versions, the hot area/cold area, size ratio is as great as ten or twenty. Larger ratios are fully anticipated but the effect is pronounced when the ratio is greater than three.

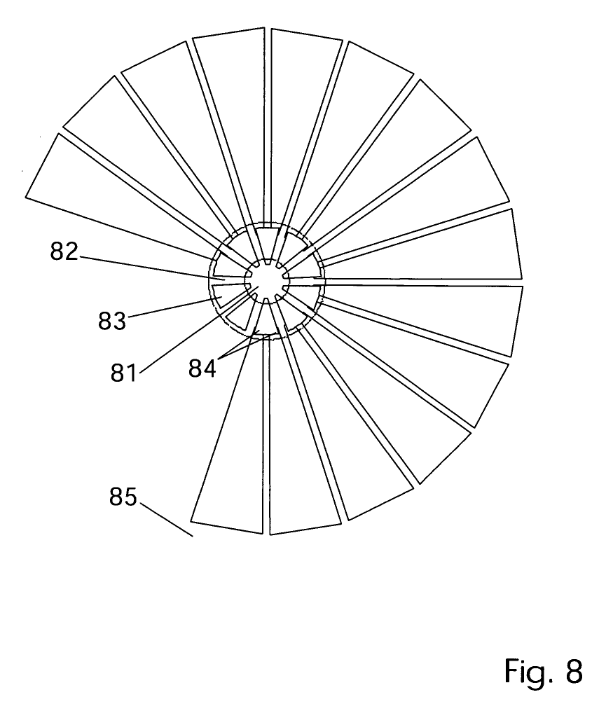

FIG. 8 shows a system with a portion cut away to accommodate reference numerals. The following discussion which relates to details of elements at the systems center is more clearly understood in view of this drawing. The space at the center 81 is useful for having placed therein a heat source or object to be cooled; sometime herein referred to as the active object. Generally this is a high performance electronic device which would fail when exposed to excess heat. So, heat transfer systems of these inventions are used to cool those high performance devices placed at the active area or center as shown. The cold area 82 (the area between the dotted lines) pulls heat from the center and into the cold contacts 83. These contacts are cold because they are thermally coupled to and sometimes form part of a P-N junctions having current passing therethrough in a manner which induces the Peltier cooling effect. Each contact is connected to both one ‘P’ type element and one ‘N’ type element at points 84. This junction may be formed via a special solder joint appropriate for use with the particular material from which the Peltier elements are made. The present inventions of special geometries are not improved by nor detracted from as a result of choice of materials and compositions. In all cases, the connectors at the cold ends, soldered to pie-wedge shaped Peltier elements extract heat from the center and transmit it radially toward the system periphery 65 where the heat may be further dissipated.

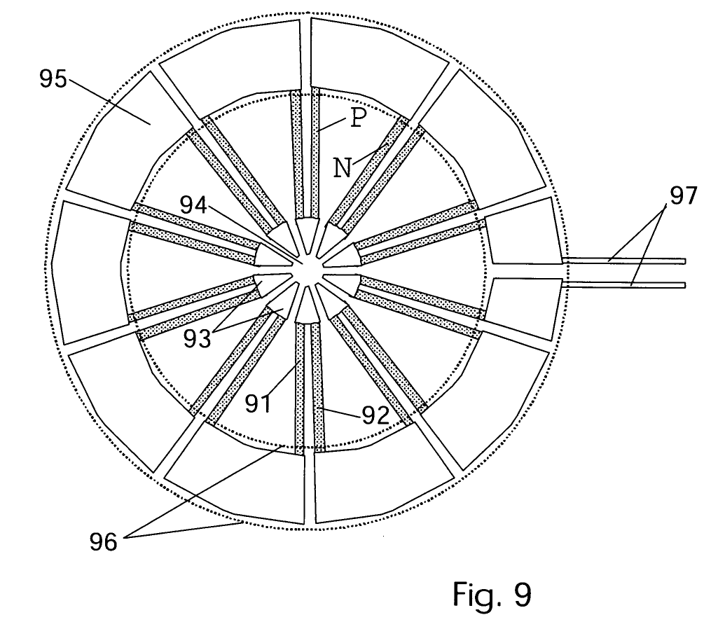

While most preferred versions include pie-wedge shaped Peltier elements, it is possible to provide a similar advantage with more common cylindrically shaped Peltier elements in the special geometric arrangement presented as FIG. 9. An elongated by cylindrically symmetric Peltier element 91 of ‘P’ type and element 92 of ‘N’ type can be combined to form the Peltier pair without the complexity of non-rectangular shaped crystals and difficulties of cutting same crystals. The geometry still provides an advantage as the hot area is still considerably larger than the cold area. In addition, the system is still constructed in a plane which is advantageously compatible with electronic systems fabrication (i.e. circuit board architectures). Cold connectors 93 collect heat from the active region 94 and passes the heat radially via Peltier elements to hot connectors 95 arranged in a circular section, or annulus demarked by dotted lines to define a hot area 96. Electric current enters and leaves the device through leads 97 to effect cooling at the center.

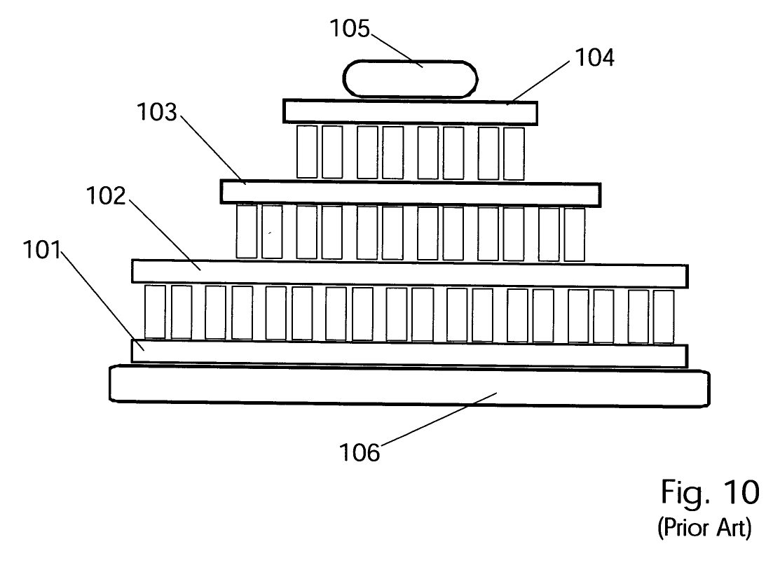

While the reader will surely now firmly appreciate the advantage realized in these systems which have a very large hot area in comparison to the cold area, it is never-the-less instructive to refer back to the systems commonly found as state of the art. In prior art systems depicted in FIG. 10, a three stage device is seen to have increasing area at the hot sides. A hot side layer 101 lies parallel to another layer 102 which effectively is a first stage cold side and simultaneously a second stage hot side. Similarly, going further in an orthogonal direction, layer 103 is a second stage cold side while also being a third stage hot side. The coldest surface 104, a third stage cold side, couples to the load 105. The load and sink 106, are in parallel planes far removed from each other due to the thickness of the heat transfer system. The area ratio, hot side/cold side, after several stages and a very thick device is about two.

It is difficult, if not impossible, to get an area ratio as great as one gets naturally in the new systems presented in this disclosure. Further, the construction of the systems in the art tend to be built in a direction orthogonal with respect to the working plane (i.e. circuit board) of the overall electronic layout, a significant disadvantage in many arrangements. Contrarily, systems of these inventions remain planar and the hot/cold area ratio may be increased without practical limit without increasing the thickness of the system. This is due to the fact that the cold area, hot area and semiconductor elements therebetween all lie in the substantially the same plane.

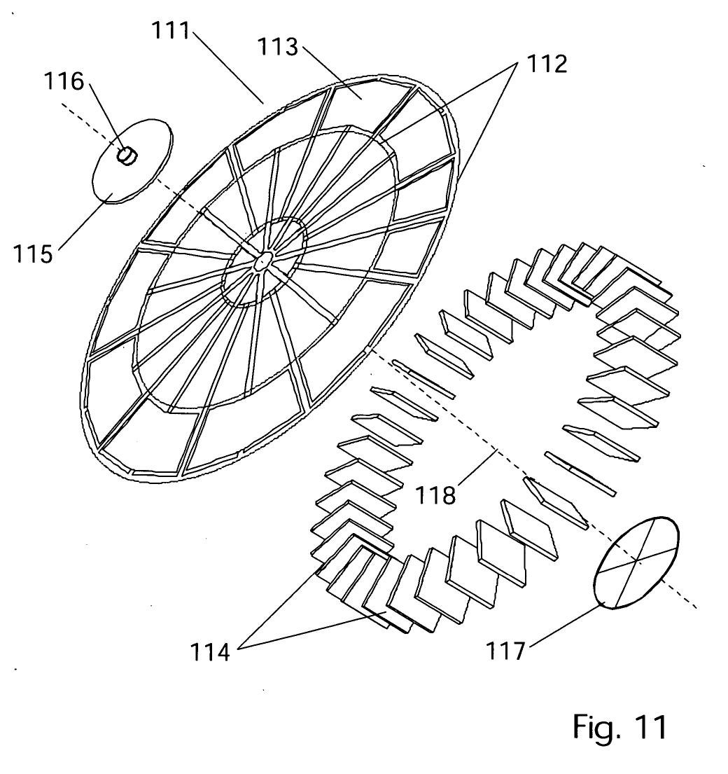

While the entire heat transfer device is now easily understood as a stand alone unit, one gains further appreciation when considering the interface between the device and those exterior systems to which it is designed to be coupled. While most of the preceding disclosure is directed to heat transfer systems as stand-alone systems, it is also important to consider how it relates and interfaces with components used in conjunction with these heat transfer systems. For example, the physical structure and geometries of heat sources and heat sinks which are appropriate for use with these devices is worthy of some detailed discussion. Both the heat source and heat sink and their intrinsic characteristics and interfaces in view of the proposed system configurations imply unique relationships and behaviors which are not found in systems previously known. As it is a fundamental function of these devices to remove heat from a source and deposit that heat at a sink, we consider here a few possibilities for the heat sink component. Typically, heat is emitted into a surrounding environment. Many electronic systems simply use a fan to blow air about; these air currents carrying heat away from hot components. Where air currents must cool devices which generate significant heat in relation to their size, then sometime a heat sink includes a cooling fin arrangement to increase the surface area. A material of high thermal conduction exposes a great surface area to air currents and provides efficient heat transfer from an heated area to the surrounding environment. Accordingly, these systems sometimes enjoy use of a cooling fin arrangement; and in certain cases particular cooling fin arrangements. The interface between these heat transfer systems and a cooling fin set is the hot area. A cooling fin set can be configured to form a thermal coupling to the hot area of systems presented in previous graphs. This can be more fully understood in view of the exploded view diagram of FIG. 11. A heat transfer system 111 has a hot area demarked by dotted lines 112 at the periphery of a disc which defines a system plane. Hot connectors 113 transmit heat via conduction to the hot area. Heat in the hot areas is passed into an array of cooling fins 114 which operate to further transmit the heat into the surrounding air. Since preferred versions of these inventions include a hot area which is annular, a cooling fin arrangement as shown is most suitable for being coupled to annular areas. A fan 117 blowing air upwardly along axis 118 causes good airflow over cooling fins. Thus, the Peltier heat transfer systems of these inventions are fully compatible with external heat management technique and mechanism.

The examples above are directed to specific embodiments which illustrate preferred versions of devices and methods of these inventions. In the interests of completeness, a more general description of devices and the elements of which they are comprised as well as methods and the steps of which they are comprised is presented herefollowing.

One will now fully appreciate how Peltier effect semiconductor heat transfer systems may be configured to support construction on planar substrates having high hot:cold area ratios. Although the present inventions have been described in considerable detail with clear and concise language and with reference to certain preferred versions thereof including best modes anticipated by the inventors, other versions are possible. Therefore, the spirit and scope of the invention should not be limited by the description of the preferred versions contained therein, but rather by the claims appended hereto.

What is claimed is

1) Peltier effect semiconductor heat transfer systems comprising:
at least one semiconductor element pair arranged to yield Peltier effect heat transfer, said semiconductor element pair comprising one ‘P’ type doped semiconductor element and one ‘N’ type doped semiconductor element, each element having a cold end and a hot end, further said element pair being arranged to form a serial electronic circuit and parallel thermal circuit,
an active area thermally coupled to the cold ends of said at least one ‘P’ type doped semiconductor element and one ‘N’ type doped semiconductor element; and
a hot area thermally coupled to the hot ends of said at least one ‘P’ type doped semiconductor element and one ‘N’-type doped semiconductor element, said hot ends being appreciably larger than said cold ends.

2) Peltier effect semiconductor heat transfer systems of claim 1, said cold ends arranged to form a single contiguous cold area characterized as a circle, said hot ends arranged to couple to and form a single contiguous hot area characterized as an annulus, said hot area annulus being concentric with said cold area circle.

3) Peltier effect semiconductor heat transfer systems of claim 1, where ‘appreciably larger’ is further defined as said hot ends having greater than 10% more area than said cold ends.

4) Peltier effect semiconductor heat transfer systems of claim 1, said semiconductor elements are substantially planar having a thickness which is a fraction of its lateral extent in an orthonormal plane.

5) Peltier effect semiconductor heat transfer systems of claim 4, where ‘fraction’ is 0.25 or less.

6) Peltier effect semiconductor heat transfer systems of claim 1, said active area, semiconductor elements, and heat dump interface are in substantially the same plane.

7) Peltier effect semiconductor heat transfer systems of claim 1, said hot area is coupled to a heat radiator which transfers heat to surrounding air.

8) Peltier effect semiconductor heat transfer systems of claim 7, said hot area is coupled to a cooling fins system to further increase the surface/air interaction area.

9) Peltier effect semiconductor heat transfer systems of claim 1, comprising a plurality of repeat elements identically formed and arranged about an axis to form a wheel shaped radially symmetric system of FIG. 2.

10) Peltier effect semiconductor heat transfer systems of claim 9, each element pair is further connected electronically to forms a single serial electronic circuit and further connected thermally to form a parallel thermal circuit of radial nature.

11) Peltier effect semiconductor heat transfer systems of claim 1, said system is further comprised of a diode as heat generating element thermally coupled at the active area.

12) Peltier effect semiconductor heat transfer systems of claim 11, said diode is high performance light emitting diode.

13) Peltier effect semiconductor heat transfer systems of claim 1, each semiconductor element being fashioned in as a substantially planar element having a non-rectangular periphery defining at least two ends.

14) Peltier effect semiconductor heat transfer systems of claim 13, said non-rectangular periphery forms a pie-wedge shape.

15) Peltier effect semiconductor heat transfer systems comprising:
at least one semiconductor element pair arranged to yield Peltier effect heat transfer, said semiconductor element pair comprising at least one ‘P’ type element and one ‘N’ type element, each element having a cold end and a hot end;
an active area thermally coupled to cold ends of said at least one ‘P’ type element and one ‘N’ type element; and
a hot area thermally coupled to the hot ends of said at least one ‘P’ type element and one ‘N’ type element;
said hot ends being appreciably larger than said cold ends.

16) Peltier effect semiconductor heat transfer systems of claim 15, said hot ends being 1.2 times or greater than said cold ends.

17) Peltier effect semiconductor heat transfer systems of claim 16, said hot ends being 3 times or greater than said cold ends.

18) Peltier effect semiconductor heat transfer systems of claim 15, said semiconductor elements are pie-wedge shaped.

19) Peltier effect semiconductor heat transfer systems of claim 15, said semiconductor elements are rectangular and arranged in a radial fashion.

20) Peltier effect semiconductor heat transfer systems of claim 19, said hot connectors lie in an annular region concentric with cold connectors which lie in an annular or circular region interior and concentric therewith.
